(19) United States
(12) Patent Application Publication
(10) Pub. No.: US 2015/0168853 A1
(43) Pub. Date: Jun. 18, 2015

(54) LITHOGRAPHY APPARATUS WITH RESTRICTED MOVEMENT RELATIVE TO FLOOR AND RELATED METHOD

(71) Applicant: Carl Zeiss SMT GmbH, Oberkochen (DE)

(72) Inventors: Mathias Schumacher, Aachen (DE); Burkhard Corves, Hergenrath (BE); Jens Kugler, Aalen (DE); Markus Knuefermann, Aalen (DE); Bernhard Geuppert, Aalen (DE); Stefan Xalter, Oberkochen (DE); Bernhard Gellrich, Aalen (DE)

(21) Appl. No.: 14/579,245

(22) Filed: Dec. 22, 2014

Related U.S. Application Data
(62) Division of application No. 13/934,908, filed on Jul. 3, 2013, now abandoned.
(60) Provisional application No. 61/672,356, filed on Jul. 17, 2012.

(30) Foreign Application Priority Data
Jul. 17, 2012 (DE) 102012212503.5

(51) Int. Cl. G03F 7/20

(52) U.S. Cl. CPC G03F 7/70825; G03F 7/70725

(57) ABSTRACT

A lithography apparatus is disclosed, which comprises: a first component, a second component, a coupling device which is configured to couple the first and second components to one another, a capture device for capturing a movement of a floor on which the lithography apparatus stands, and a control device which is configured to actuate the coupling device depending on the captured movement of the floor in order to restrict a movement of the second component relative to the first component.

### CROSS-REFERENCE TO RELATED ART

This application is a division of, and claims priority under 35 USC 120 to, U.S. application Ser. No. 13/934,908, filed Jul. 3, 2013, which claims the benefit of U.S. provisional application No. 61/672,356, filed Jul. 17, 2012, and German patent application No. DE 10 2012 212 503.5, filed Jul. 17, 2012, the entire disclosures of which are herein incorporated by reference.

The invention relates to a lithography apparatus, in particular an EUV lithography apparatus, and a method.

By way of example, lithography apparatuses are used in the production of integrated circuits (ICs) for imaging a mask pattern in a mask onto a substrate such as e.g. a silicon wafer. Here, a light beam generated by an optical system (POB) is directed at the substrate through the mask.

Driven by Moore's law and the pursuit of ever smaller structures, particularly in the production of integrated circuits, EUV lithography apparatuses are currently being developed which use light with a wavelength in the region of 5 nm to 30 nm, in particular 13.5 nm. “EUV” denotes “extreme ultraviolet”. As a result of most materials exhibiting high absorption of light at this wavelength, it is necessary to use reflective optical units, i.e. mirrors, in place of—as previously—refractive optical units, i.e. lenses, in such EUV lithography apparatuses. The individual components of the optical system of the lithography apparatus have to be positioned very precisely in relation to one another, in particular in the pm range, and have to be decoupled from all vibration stimuli. Very soft mounting of the components is advantageous for this. If there now are vigorous movements of the base of such a lithography apparatus, for example as a result of an earthquake, all components are excited to vibrate, in particular in all six degrees of freedom. As a result of the soft mounting of the components, there now are large relative movements between these. In particular, very large relative movements can be recorded between the mirrors and the force frame. This can lead to damage to the components, for example by a mirror impacting on a sensor.

An object of the present invention then consists of developing a lithography apparatus in which damage to components of the lithography apparatus is avoided when a floor on which the lithography apparatus stands moves. A further object of the present invention consists of developing a method for avoiding damage to a lithography apparatus.

This object is achieved by a lithography apparatus comprising a first component, a second component, a coupling device, a capture device and a control device. The coupling device is configured to couple the first and second components to one another. The capture device is configured to capture a movement of the floor on which the lithography apparatus stands. The control apparatus is configured to actuate the coupling device depending on the captured movement of the floor in order to restrict a movement of the second component relative to the first component.

A concept on which the present invention is based consists of providing a coupling device which is controlled by a control device and can therefore actively react to movements of the floor. This reaction then consists of coupling the first and second components to one another, wherein the coupling can, in particular, comprise force fit-type or interlocking coupling. Furthermore, the coupling can be brought about by contact or without contact.

By way of example, the control device can be provided in the form of a microprocessor.

“Coupling” means bringing the first and second components into a mechanical or electromagnetic functional connection. Here, the coupling between the first and second components need not necessarily be direct. That is to say the first and second components can also be coupled to one another indirectly via a third, fourth and further component. That is to say, the first and second components can, for example, be coupled to one another by virtue of the fact that these are respectively fixed in relation to a common force frame of the lithography apparatus.

In accordance with one embodiment, the control device comprises a comparison unit for providing a comparison result depending on a comparison of the captured movement and at least one reference pattern, and a control unit which actuates the coupling device for restricting the movement of the second component relative to the first component depending on the comparison result. By way of example, the reference pattern can comprise an allowed amplitude range of the captured movement, an allowed frequency range of the captured movement, an allowed time duration of the captured movement, an allowed energy of the captured movement or a combination thereof.

By way of example, the at least one reference pattern corresponds to an earthquake. In the case of an earthquake, different types of waves propagate from the focus. Initially, body waves propagate in all spatial directions. These arrive on the surface of the earth, where they generate surface waves. Both body and surface waves arrive at any given location. In the case of body waves, a distinction can be made between P-waves (primary waves) and S-waves (secondary waves), and, in the case of surface waves, a distinction can be made between L-waves (Love waves) and R-waves (Rayleigh waves). The reference pattern can now correspond to one or more of the aforementioned waves in respect of their amplitude, their frequency, their time duration, their energy and/or their spatial direction. The reference pattern preferably represents an earthquake in its three spatial directions, but two or only one spatial direction(s) are also possible. The reference pattern preferably corresponds to merely part of a wave or the waves.

The at least one reference pattern preferably corresponds to a P-wave. P-waves propagate as pressure waves (longitudinal waves) through the earth. By contrast, S-waves are shear waves (transverse waves) and carry most of the seismic energy. By way of example, the ratio of the two waves can be specified by Energy_{p-wave}/Energy_{S-wave}=1/25. Moreover, there is a difference in the propagation speed of the two wave types, and so a different propagation time to the location can be observed. By way of example, depending on the conditions underground, the P-wave propagates twice as fast as the energy-rich S-wave. The L- and R-waves arrive at the location shortly after the S-wave. The arrival of the L- and R-waves is connected with vigorous horizontal ground movements. Hence, a reference pattern that corresponds to the P-wave is advantageously selected, such that the earthquake can be identified and the control unit can actuate the coupling device accordingly before the energy-rich S-, L- and R-waves arrive at the location, which waves constitute a serious threat to the lithography apparatus and can lead to damage to the first and/or second component if no appropriate precautions are taken.

In accordance with a further embodiment, the control unit is configured to actuate the coupling device immediately for restricting the movement of the second component relative to the first component when the comparison result is such that the captured movement corresponds to the at least one reference pattern. As already mentioned above, this for example enables the second component to be fixed in relation to the first component before the energy-rich S-, L- and R-waves arrive at the lithography apparatus.

In accordance with one embodiment, the movement of the floor that can be captured by the capture device is a travel, a speed and/or an acceleration in one or more spatial directions. By way of example, the capture device can be embodied in the form of an accelerometer. The accelerometer can be embodied as a piezoelectric accelerometer, a strain gauge or an accelerometer which measures via magnetic induction. The capture device can measure the movement of the floor indirectly. Such an indirect measurement can provide for the movement of the base of the lithography apparatus being captured, as a result of which conclusions can be drawn in respect of the floor movement. A strain gauge can be used to measure the deformation on a structure of the lithography apparatus such that the movement of the floor can also be deduced indirectly in this case. Furthermore, it is also possible to measure the movement of the floor directly, for example via an optical sensor which has a reference point on the floor.

In accordance with a further embodiment, the coupling device is configured to restrict the movement of the second component relative to the first component in relation to a travel, a speed and/or an acceleration of the second component in one or more spatial directions. Depending on the application, it may, for example, be expedient to restrict a travel of the second component in order to avoid impact between the second component and the first component or a third component, for example a structure or a frame, more particularly a force frame, or a sensor of the lithography apparatus. Additionally, or as an alternative thereto, it is possible to restrict the speed and/or the acceleration of the second component. By way of example, an excessive acceleration of the second component, in particular of a large mirror, could lead to a significant deformation of or other permanent damage to the second component as a result of the floor movement. Such damage can be avoided by the acceleration of the second component now being restricted.

The coupling device can be configured to restrict the movement of the second component relative to the first component by a force fit, by an interlock, by contact and/or without contact. The force fit in particular can be embodied in a contacting or contactless fashion. By way of example, a mechanical brake, in particular with corresponding brake pads, can be provided for a contacting force fit. An induction brake which brings about an electromagnetic force fit can be used for a contactless force fit. By way of example, a contacting interlock can be brought about by one or more receiving elements and one or more engaging elements engaging into one another. By way of example, the interlock allows a travel of the second component to be restricted in a simple fashion, whereas a speed or an acceleration of the second component can easily be restricted via the force fit.

In accordance with one embodiment, the coupling device for restricting the movement of the second component relative to the first component comprises an actuator, a spring with a changeable spring stiffness, a damper with a changeable damping constant and/or an adjustable end stop. By way of example, the actuator is well suited to actuating the aforementioned engaging and/or receiving mechanism, in particular locking pins which interact with locking recesses. By way of example, the spring stiffness of the spring can be set by virtue of the fact that a direction in which the second component acts on the spring is modified. By way of example, the damping constant can be set by virtue of the fact that, in the case of a fluid damper, passage openings for the fluid from a high-pressure side to a low-pressure side are increased or decreased in size. By way of example, the end stop can be set by virtue of the fact that it can be driven directly against the second component, i.e. brought into contact therewith, for restricting the movement of the second component.

By way of example, the coupling device for the interlocking restriction of the movement comprises a locking unit which is configured to lock the second component relative to the first component in a releasable manner. By way of example, the locking unit can comprise locking pins and locking openings, which interact in such a way that the second component is fixed in relation to the first component.

In accordance with one embodiment, the coupling device for the force fit-type restriction of the movement can comprise a mechanical brake or an induction brake. By way of example, the mechanical brake can comprise one or more brake pads. In one possible embodiment, the induction brake comprises a coil fixedly connected to the first or second component, which coil interacts with a coil that can be actuated by the control device.

The spring stiffness of the spring can be provided to be changeable by pivoting the spring.

In accordance with one embodiment, the capture device is provided on a structure or in a base of the lithography apparatus.

The first component can be embodied as a structure, in particular a frame. By way of example, the frame can be a force frame or a sensor frame. The force frame absorbs the substantial forces occurring during the operation of the lithography apparatus. By way of example, these forces include the forces resulting from holding a mirror. The sensor frame is decoupled from the force frame by appropriate damping elements and merely absorbs the forces resulting from holding the sensors, i.e. practically no forces, during the operation of the lithography apparatus.

The second component can be embodied as a mirror of the lithography apparatus. Particularly when holding mirrors, the requirement that emerges is that these mirrors are to be protected from, in particular, an earthquake or other floor movements, since these mirrors are particularly sensitive.

Furthermore, provision is made for a method for avoiding damage to a lithography apparatus comprising a first and a second component when a floor on which the lithography apparatus stands moves. In the method, a movement of the floor is captured and a movement of the second component relative to the first component is restricted depending on the captured movement.

The features and developments explained above for the lithography apparatus according to the invention apply accordingly to the method according to the invention.

Further exemplary embodiments will be explained in more detail with reference to the attached figures of the drawings.

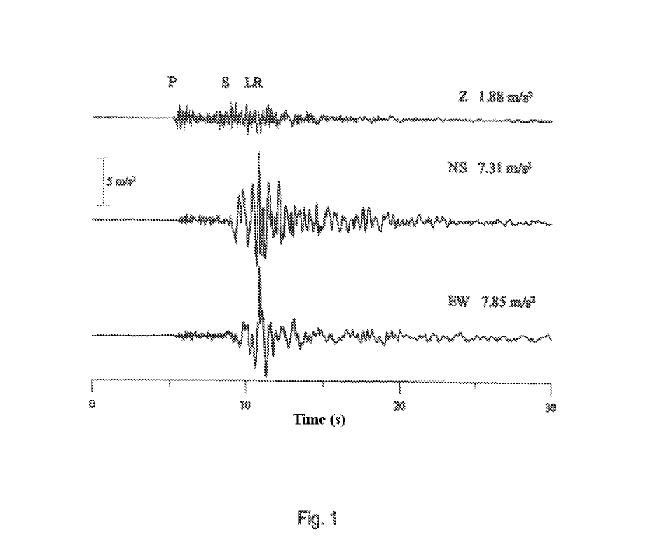

FIG. 1 shows floor accelerations in three mutually orthogonal directions for an exemplary earthquake;

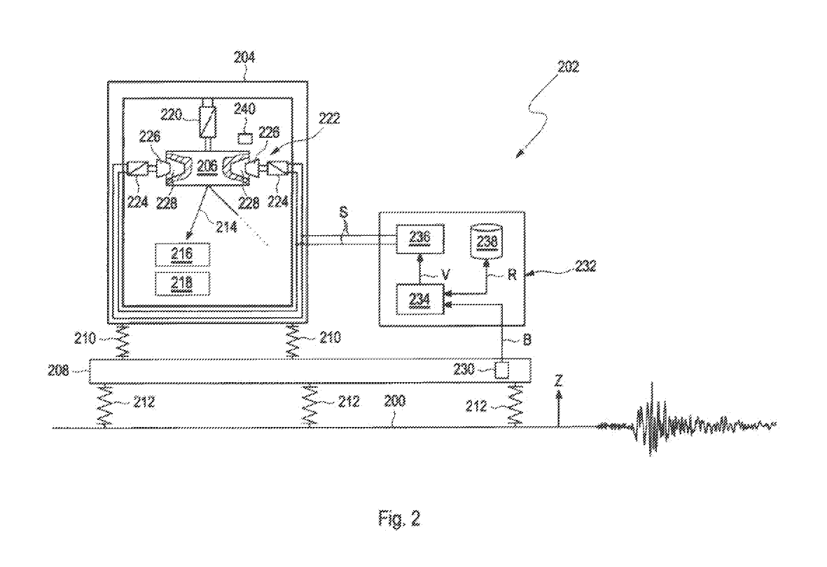

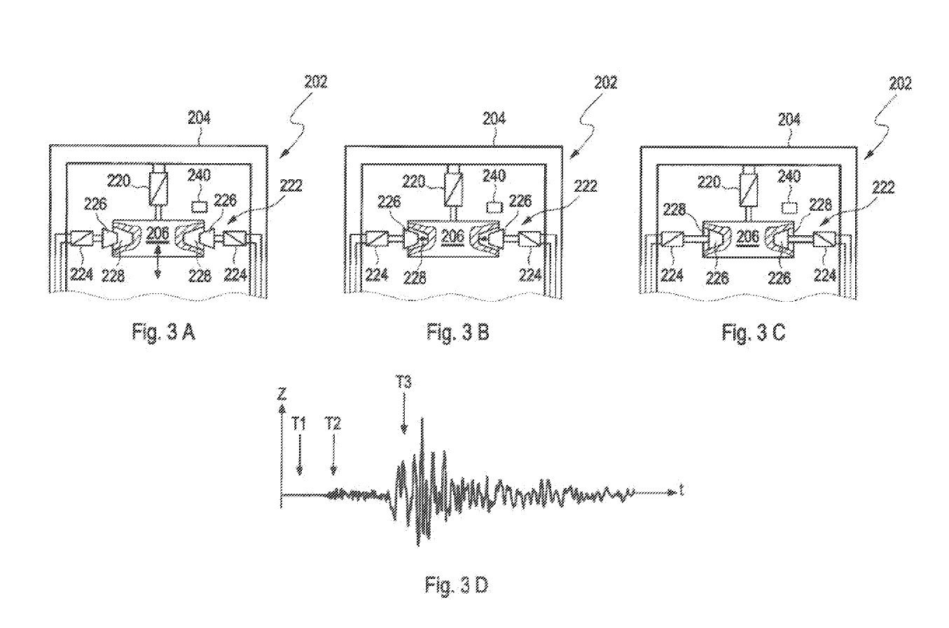

FIG. 2 schematically shows a lithography apparatus in accordance with one embodiment;

FIGS. 3A-3D show a chronological sequence of a method in accordance with one embodiment;

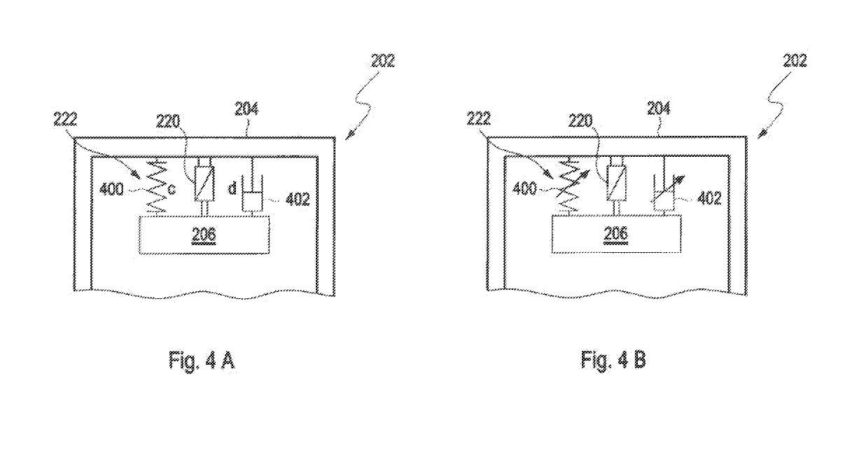

FIGS. 4A and 4B show, in section, a lithography apparatus in accordance with a further embodiment, in different states;

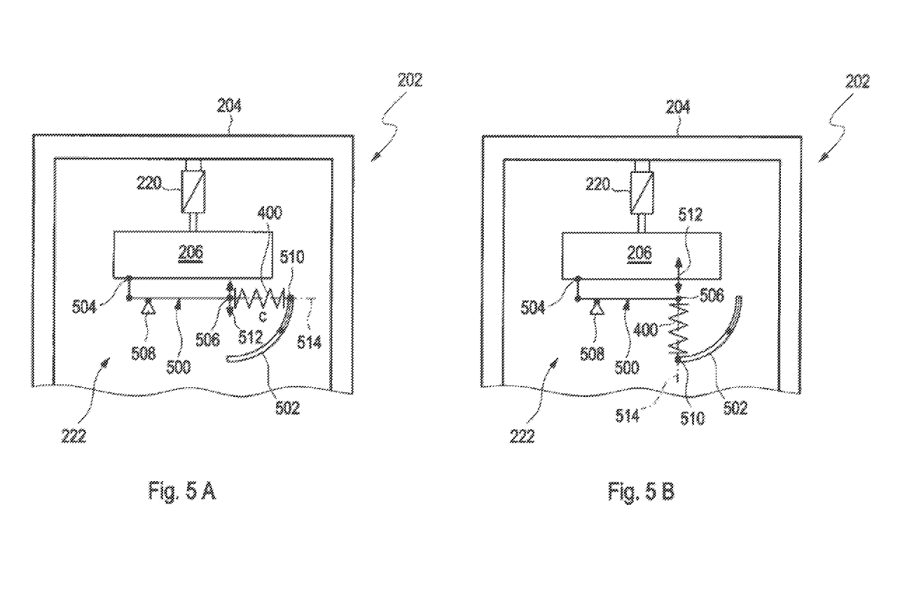

FIGS. 5A and 5B show, in section, a lithography apparatus in accordance with a further embodiment, in different states;

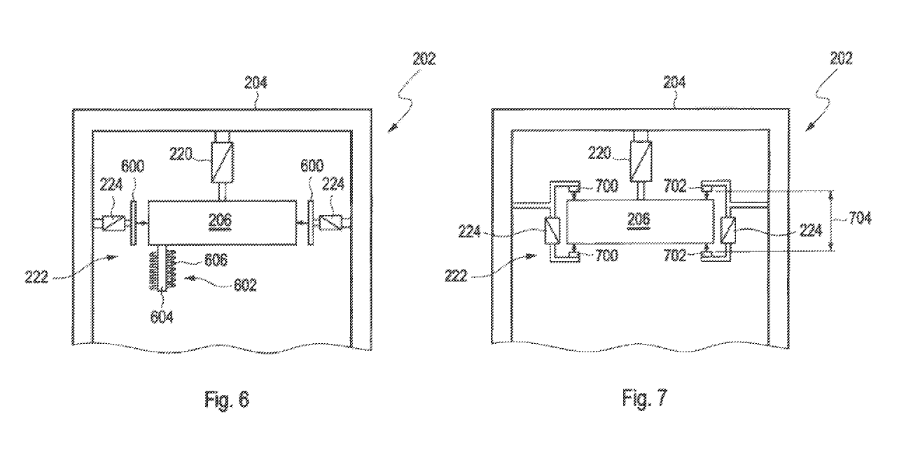

FIG. 6 shows, in section, a lithography apparatus in accordance with a further embodiment;

FIG. 7 shows, in section, a lithography apparatus in accordance with a further embodiment; and

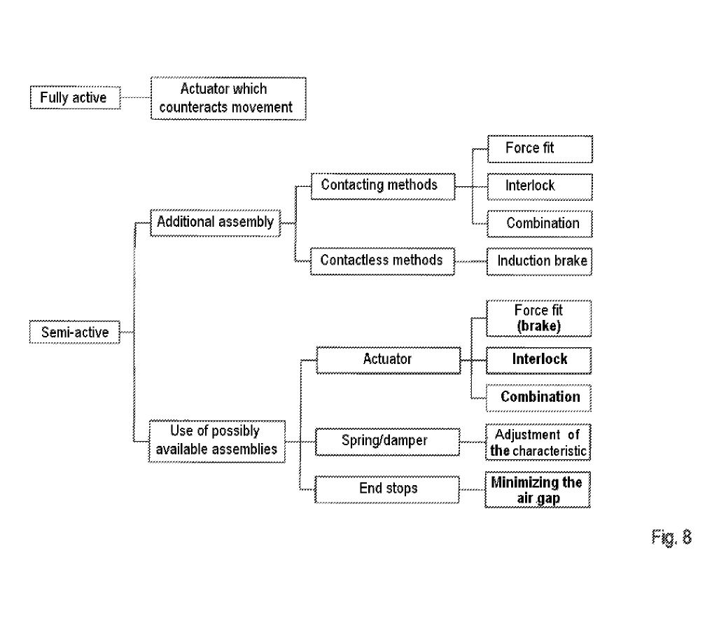

FIG. 8 shows a classification of solution options.

If nothing else is specified, the same reference signs in the figures denote the same or functionally equivalent elements. Furthermore, it should be noted that the illustrations in the figures are not necessarily to scale.

FIG. 1 shows exemplary floor accelerations in three mutually orthogonal directions Z, NS, EW for an exemplary earthquake with a magnitude of 7.3 and an epicentral distance of 39 km. Z denotes a vertical movement direction (see also FIG. 2) of a floor 200 on which a lithography apparatus 202 stands. NS (North/South) and EW (East/West) respectively denote horizontal movements of the floor 200 at the location of the lithography apparatus 202.

It can be seen from FIG. 1 that the maximum horizontal accelerations (NS, EW) are significantly larger than the vertical acceleration (Z). Moreover, it can clearly be seen that the P-wave reaches the location first. As a result of the small distance from the epicenter, the S-wave and the L- and R-waves arrive almost simultaneously and approximately 5 seconds after the P-wave. The acceleration amplitude caused by the P-wave, particularly in the vertical direction Z, is large enough to be able to detect the latter clearly and distinguish it from normal floor movements. This enables an early detection of an earthquake. That is to say, the detection of the P-wave renders it possible to prepare the lithography apparatus 202 in FIG. 2 for the arrival of the S- and also L- and R-waves, which are connected with correspondingly vigorous movements of the floor 202, in order thus to avoid damage to components of the lithography apparatus 202.

FIG. 2 shows, in a schematic view, the lithography apparatus 202 in accordance with one embodiment.

The lithography apparatus 202, which is preferably embodied as an EUV lithography apparatus, comprises a first component 204 and a second component 206. By way of example, the first component 204 is embodied as a force frame, which absorbs all substantial forces during the operation of the lithography apparatus 202 and dissipates these to the floor 200 via a base 208 of the lithography apparatus 202. The force frame 204 can be supported on the base 208 by one or more springs 210 or else by several dampers. By way of example, the springs 210 can be formed by bolts, via which the force frame 204 is screwed into the base 208. The base 208 can in turn be supported elastically on the floor 200, which is indicated by corresponding springs 212.

The second component 206 can, for example, be embodied as a mirror. The mirror 206 can be provided for guiding a light ray 214 onto a photomask 216. By way of example, the mirror 206 can be embodied as a facet and/or hollow mirror. It is naturally also possible for several mirrors 206 to be provided. The photomask 216 has a structure which is imaged on a wafer 218 in a reduced manner.

In place of the mirror 206, the second component could also be embodied as a light source, in particular an EUV (extreme ultraviolet) light source, a collimator or a monochromator.

During normal operation of the lithography apparatus 202, an actuator 220 generates a magnetic field in which the mirror 206 levitates. In so doing, the mirror 206 has to be positioned very precisely in relation to the photomask 216 and/or further mirrors.

The lithography apparatus 202 furthermore comprises a coupling device 222. By way of example, the coupling device 222 comprises two actuating members 224, in particular solenoids, which are fixed on the force frame and respectively configured to bring an—in particular conical—locking pin 226 into mutual engagement with a locking opening 228 which can have a corresponding conical embodiment. This bringing into engagement leads to the mirror 206 being connected by interlock to the force frame 204 in all three spatial directions and therefore no longer being able to move relative to the latter. Together, the actuating members 224, the locking pins 226 and the locking openings 228 form a locking unit.

The lithography apparatus 202 furthermore comprises a capture device 230. By way of example, the capture device 230 is embodied in the form of an accelerometer. The accelerometer 230 can be embodied as a piezoelectric accelerometer. Furthermore, the accelerometer 230 can be arranged in the base 208, more particularly integrated into the latter. The accelerometer 230 is configured to capture a movement of the floor 200. In particular, the accelerometer 230 can be provided for merely capturing the movement of the floor in the Z-direction.

The lithography apparatus 202 furthermore comprises a control device 232. The control device 232 can in turn be composed of a comparison unit 234, a control unit 236 and a memory unit 238. The control device 232 is configured to actuate the coupling device 222 in order to restrict a movement of the mirror 206 relative to the force frame 204 depending on a captured movement of the floor 200. In accordance with the exemplary embodiment, this restriction should occur when an earthquake is to be expected, which earthquake has such qualities that it is foreseeable that the lithography apparatus 202, in particular the mirror 206, would be damaged. By way of example, this damage could result from the mirror 206 covering a distance due to the earthquake, which leads to a collision between the mirror 206 and e.g. the force frame 204 or a sensor 240 which, during normal operation of the lithography apparatus 202, is configured to interact with the mirror 206, for example in order to capture a position of the latter.

During normal operation of the lithography apparatus 202, i.e. when e.g. the wafer 218 is exposed, the control unit 236 actuates the actuating members 224 of the coupling device 222 in such a way that the locking pins 226 are not engaged with the locking openings 228. Accordingly, the mirror 206 can be moved freely in space via the actuator 220 in order to control the light ray 214 accordingly.

In so doing, the accelerometer 230 continuously captures the movement of the floor 200 in the Z-direction (and/or in the NS- and/or EW-direction). The accelerometer 230 provides an acceleration signal B for the comparison unit 234, to which it is coupled in terms of signals. The comparison unit 234 compares the acceleration signal B with a reference pattern R, which the comparison unit reads from the memory unit 238. The comparison unit 234 can also be provided to read out a multiplicity of reference patterns R1 to Rn from the memory unit 238.

After this, the comparison unit 234 compares the acceleration signal B to the reference pattern R. The reference pattern R corresponds to part, e.g. the first two seconds, of a P-wave of an earthquake. By way of example, the reference pattern can define an allowed amplitude-, frequency-, energy- or time-duration range. The reference pattern R can also comprise combinations of these allowed ranges. Furthermore, the reference pattern R can define these allowed ranges in different spatial directions, in particular in the three mutually orthogonal spatial directions Z, NS, EW. Depending on the comparison between the acceleration signal B and the reference pattern R, the comparison unit 234 generates a comparison result V. Depending on the comparison result V, the control unit 236 generates a control signal S for actuating the actuating members 224. If the acceleration signal B lies outside of the allowed range, i.e. if a strong earthquake is arriving at the location of the lithography apparatus 202, the control unit 236 actuates the actuating members 224 in such a way that the locking pins 226 come into engagement with the locking openings 228 and hence the mirror 206 is fixed in relation to the force frame 204. When the S-, L- and R-waves now subsequently arrive at the location of the lithography apparatus 202, which usually occurs a few seconds after the arrival of the P-wave, the mirror 206 is securely locked. The mirror 206 is then unable to move relative to the force frame 204 as a result of the vigorous movements of the floor 200 due to the S-, L- and R-waves, as a result of which a collision of the mirror 206 with the frame 204 and/or the sensor 240 is avoided.

FIGS. 3A-3D show a chronological sequence of the method explained above in conjunction with FIGS. 1 and 2.

At the time T1, the locking pins 226 do not engage with the locking openings 228 of the mirror 206. The lithography apparatus 202 accordingly is in normal operation. At the time T2, the P-wave is captured by the accelerometer 230. The control unit 236 thereupon drives the locking pins 226 into the locking openings 228 via the actuating members 224. At the time T3, i.e. at the start of the intensive movement phase due to the S-, L- and R-waves, the mirror 206 is connected to the force frame 204 by interlock in all three spatial directions. By way of example, two to eight, in particular three to six, seconds can lie between the time T2 and the time T3.

FIGS. 4A and 4B show, in section, a lithography apparatus 202 in accordance with a further embodiment. In this—in contrast to FIG. 2—the coupling device 222 is formed by e.g. a spring 400 and/or a damper 402. Here, the spring stiffness c or the damping constant d of the spring 400 and the damper 402, respectively, can be set, as indicated in FIG. 4B. By way of example, the spring stiffness c of the spring 400 can be set by lengthening or shortening the available deflection travel. In the case of a damper 402 embodied as, for example, a fluid damper, the damping constant d can be controlled by modifying passage openings of a fluid, e.g. oil, of the damper from a high-pressure side to a low-pressure side.

Here, FIG. 4A shows the normal operation at the time T1, see FIG. 3A. At the time T2, i.e. in the announcement phase of the earthquake, the control unit 236 actuates the coupling device 222 in such a way that the spring stiffness c and/or the damping constant d are modified, in particular increased, in such a way that during the intensive movement phase at the time T3, see FIG. 3C, a movement, e.g. a travel, of the mirror 206 is restricted in such a way that a collision with the force frame 204 and/or the sensor 240, see FIG. 2, is avoided.

FIGS. 5A and 5B respectively show, in section, a lithography apparatus 202 in accordance with a further embodiment.

In contrast to FIG. 2, the lithography apparatus 202 in accordance with the exemplary embodiment according to FIGS. 5A and 5B comprises a coupling device 222 which comprises a lever 500, a spring 400 and a sliding-block guide 502. The coupling device 222 is configured to increase a mirror-related spring stiffness c of the spring 400 by pivoting the spring 400. On its one end 504, the lever 500 is attached to the mirror 206. On its other end 506, the lever 500 is attached to one end of the spring 400. Between the one and the other end 504, 506, the lever 500 is hinged on a pivot point 508 on e.g. the force frame 204. At its other end, the spring 400 is provided with a sliding-block element 510, which engages into the sliding-block guide 502 in a displaceable manner. By way of example, the sliding-block guide 502 can have a circular arc-shaped embodiment. However, the sliding-block guide 502 can also have a different design. In particular, what is important is that the sliding-block guide 502 enables the spring 400 to pivot about the end 506 of the lever 500.

FIG. 5A shows the normal operation at the time T1, see FIG. 3A. Movements of the mirror 206 merely lead to the end 506 being moved in a deflection direction 512 perpendicular to the longitudinal axis 514 of the spring 400. Accordingly, the spring 400 only has a low mirror-related spring stiffness c in this state.

In the announcement phase T2, see FIG. 3B, the control unit 236 actuates the coupling device 222 in such a way that the sliding-block element 510 is moved along the sliding-block guide 502 in such a way that the longitudinal axis 514 of the spring 400 is now in line with the deflection direction 512 of the end 506. As a result, the mirror-related spring stiffness c of the spring 400 increases significantly, and so movements of the mirror 206 during the intensive movement phase T3, see FIG. 3C, are greatly restricted. In place of spring 400 or in addition thereto, a damper 402 could also be used here.

FIG. 6 shows, in section, a lithography apparatus 202 in accordance with a further embodiment.

In contrast to FIG. 2, the actuating members 224 of the coupling device 222 actuate brake pads 600 in the embodiment in accordance with FIG. 6.

At the time T1, i.e. during normal operation, the brake pads 600 are at a distance from the mirror 206, and so the latter can move freely. At the time T2, i.e. during the announcement phase, the control unit 236 actuates the actuating members 224 in such a way that the brake pads 600 rest against the mirror 206 and these therefore, with force fit, fix the latter in relation to the frame 204 in all three spatial directions.

As an alternative to the brake pads 600, a further force fit connection could be achieved by virtue of provision being made for an induction brake 602. The induction brake 602 can comprise a core 604, made in particular of iron, which is provided in a coil 606 in a movable fashion at the time T1. At the time T2, the control unit 236 generates such a current flow through the coil 606 that a magnetic field is generated, which fixes the core 604, and hence the mirror 206, in relation to the force frame 204.

FIG. 7 shows, in section, a lithography apparatus 202 in accordance with a further embodiment.

In the lithography apparatus 202, provision is made, in contrast to FIG. 2, for a coupling device 222 which comprises two pairs of end stops 700, 702. The end stops 700, 702 respectively lie opposite one another and hold the mirror 206 between them. The distance 704 between the two end stops 700 and between the two end stops 702 can respectively be set via an actuating member 224. At the time T1, i.e. during normal operation, the distance 704 is large; the end stops 700, 702 do not, in particular, contact the mirror 206 at the time T1. At the time T2, the control unit 236 actuates the actuating members 224 in such a way that the distance 704 reduces. In particular, the end stops 700, 702 can be brought into contact with the mirror 206 in order thereby to obtain a interlock-type fixation of the mirror 206 in relation to the force frame 204 in at least one spatial direction, in particular in the Z-direction.

FIG. 8 shows a classification of solution options in the form of a tree structure. FIG. 8 distinguishes between fully active and semi-active solutions.

A fully active solution could consist of the control unit 236 directly actuating the actuator 220 in order to restrict the movement of the mirror 206 in relation to the force frame 204. In this case, the actuator 220 would form the coupling device 222, as shown in FIG. 2.

However, semi-active solutions, as shown in FIGS. 4 to 7, should be preferred over this, since they require only a little actuation energy. The properties of the coupling device 222 are adapted to the situation in the semi-active solutions. For the lithography apparatus 202, this means that the mirror 206 is mounted as soft as possible during normal operation and therefore decoupled from vibrations, e.g. of the force frame 204. As soon as high dynamic loads act on the lithography apparatus 202, as may be the case as a result of an earthquake, the properties of the coupling device 222 are modified in such a way that the relative movement between the mirror 206 and other components of the lithography apparatus 202, in particular the force frame 204, is small. It is stressed once again at this point that, instead of the earthquake, other movements of the floor, for example as a result of an explosion, could lead to damage to the lithography apparatus 202. Therefore, it is also possible for a reference pattern (or several reference patterns) adapted to this case to be stored in the memory unit 238, such that the control unit 236 can also react to such excitations and therefore avoid damage to the mirror 206. It is furthermore stressed at this point that, instead of the mirror, other components 206 could also be protected from damage via the design illustrated here.

Although the invention was described on the basis of various exemplary embodiments, it is by no means restricted thereto and rather can be modified in many different ways.

### LIST OF REFERENCE SIGNS

200 Floor
202 Lithography apparatus
204 First component
206 Second component
208 Base
210 Spring
212 Spring
214 Light ray
216 Photomask
218 Wafer
220 Actuator
222 Coupling device
224 Actuating member
226 Locking pin
228 Locking opening
230 Capture device
232 Control device
234 Comparison unit
236 Control unit
238 Memory unit
240 Sensor
400 Spring
402 Damper
500 Lever
502 Sliding-block guide
504 End
506 End
508 Hinge point
510 Sliding-block element
512 Deflection direction
514 Longitudinal axis
600 Brake pad
602 Induction brake
604 Core
606 Coil
700 End stop
702 End stop
704 Distance
c Spring stiffness
d Damping constant
B Acceleration
R Reference pattern
S Control signal
V Comparison result
Z Vertical direction
NS Horizontal direction
EW Horizontal direction

1.-15. (canceled)

16. A lithography apparatus, comprising:
a first component;
a second component;
a coupling device configured to couple the first and second components to each other;
a capture device configured to capture a movement of a floor supporting the lithography apparatus; and
a control device configured to actuate the coupling device based on the captured movement of the floor in order to restrict a movement of the second component relative to the first component,
wherein:
the coupling device is configured to restrict movement of the second component relative to the first component; and
the coupling device comprises at least one element selected from the group consisting of a spring with a changeable spring stiffness, and a damper with a changeable damping constant.

17. The lithography apparatus of claim 16, wherein the coupling device comprises a spring with a changeable spring stiffness.

18. The lithography apparatus of claim 16, wherein the coupling device comprises a spring configured to pivot to change a stiffness of the spring.

19. The lithography apparatus of claim 16, wherein the coupling device comprises a damper with a changeable damping constant.

20. The lithography apparatus of claim 16, wherein:
the control device comprises a comparison unit and a control unit;
the control device is configured to provide a comparison result based on a comparison of the captured movement and at least one reference pattern; and
the control unit is configured to actuate the coupling device to restrict movement of the second component relative to the first component based on the comparison result.

21. The lithography apparatus of claim 20, wherein the at least one reference pattern corresponds to an earthquake.

22. The lithography apparatus of claim 21, wherein the at least one reference pattern corresponds to a P-wave.

23. The lithography apparatus of claim 22, wherein the control unit is configured to immediately actuate the coupling device to restrict movement of the second component relative to the first component when the comparison result is such that the captured movement corresponds to the at least one reference pattern.

24. The lithography apparatus of claim 21, wherein the control unit is configured to immediately actuate the coupling device to restrict movement of the second component relative to the first component when the comparison result is such that the captured movement corresponds to the at least one reference pattern.

25. The lithography apparatus of claim 20, wherein the control unit is configured to immediately actuate the coupling device to restrict movement of the second component relative to the first component when the comparison result is such that the captured movement corresponds to the at least one reference pattern.

26. The lithography apparatus of claim 16, wherein the movement of the floor comprises a travel of the floor in one or more spatial directions, a speed of the floor in one or more spatial directions, and/or an acceleration of the floor in one or more spatial directions.

27. The lithography apparatus of claim 16, wherein the coupling device is configured to restrict the movement of the second component relative to the first component in relation to a travel of the second component in one or more spatial directions, a speed of the second component in one or more spatial directions, and/or an acceleration of the second component in one or more spatial directions.

28. The lithography apparatus of claim 16, wherein the capture device is on a structure of the lithography apparatus, or wherein the capture device is in a base of the lithography apparatus.

29. The lithography apparatus of claim 16, wherein the first component is a structure of the lithography apparatus.

30. The lithography apparatus of claim 16, wherein the first component is a frame of the lithography apparatus.

31. The lithography apparatus of claim 16, wherein the second component comprises a mirror.

32. A method, comprising:
providing a lithography apparatus according to claim 16;
using the capture device to capture movement of the floor; and
based on the captured movement of the floor, using the control device to actuate the coupling device to restrict movement of the second component relative to the first component.

33. The method of claim 32, wherein the coupling device comprises a spring with a changeable spring stiffness, and restricting movement of the second component relative to the first component comprises changing the spring stiffness of the spring.

34. The method of claim 32, wherein the coupling device comprises a damper with a changeable damping constant, and restricting movement of the second component relative to the first component comprises changing the damping constant of the damper.

35. A method of operating a lithography apparatus supported by a floor, the lithography apparatus comprising first and second components, the method comprising:
based on a determined movement of the floor, using a coupling device to restrict movement of the second component relative to the first component,
wherein the coupling device comprises at least one element selected from the group consisting of a spring with a changeable spring stiffness, and a damper with a changeable damping constant.
